(19) United States
(12) Patent Application Publication
(10) Pub. No.: US 2005/0224694 A1
(43) Pub. Date: Oct. 13, 2005

(54) High efficiency microlens array

(75) Inventor: Dun-Nian Yaung, Taipei City (TW)

Correspondence Address: HAYNES AND BOONE, LLP, 901 MAIN STREET, SUITE 3100, DALLAS, TX, 75202, US

(73) Assignee: Taiwan Semiconductor Manufacturing Co. Ltd., Hsin-Chu (TW)

(21) Appl. No.: 10/821,141

(22) Filed: Apr. 8, 2004

(51) Int. Cl. H01L 27/00

(52) U.S. Cl. 250/208.1

(57) ABSTRACT

A microlens array including a substrate having a plurality of photo sensors located therein, a microlens layer located over the substrate, and a dielectric film located over the microlens layer. The plurality of microlenses are separated by a plurality of gaps and the dielectric film conforms to the microlens layer, thereby filling the plurality of gaps.

### BACKGROUND

The present disclosure relates generally to microlens arrays and, more specifically, to a microlens array having a conformal dielectric layer over the microlenses.

Microlens arrays are widely employed in image sensor technology, such as charged coupling device (CCD) image sensors and complimentary metal-oxide-semiconductor (CMOS) image sensors. In general, CCD, CMOS, and other types of microlens arrays transform a light pattern (i.e., an image) into an electric charge pattern.

Microlens arrays generally include polymer or dielectric microlenses. Polymer microlenses are formed by patterning a polymer layer formed over a dielectric layer and subsequently heating the patterned polymer layer to create the required shape of each microlens. Dielectric microlenses are formed by etching a dielectric layer employing a mask or patterned layer, such as the patterned polymer layer described above. In each case, the microlenses are aligned over corresponding photo sensors formed in a substrate on which the polymer and/or dielectric layers are deposited.

Such devices, however, are susceptible to reliability problems, including thermal instability and yellowing effects. The microlenses are also separated by a gap, and these gaps can decrease the fill factor of the microlens array. The fill factor is a ratio of the photo sensor area to the total pixel area. For example, the fill factor can be less than 30% for some microlens arrays.

Accordingly, what is needed in the art is a memory device that addresses the above discussed issues, a method of manufacture thereof, and a system including the same.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 illustrates a sectional view of one embodiment of a microlens array constructed according to aspects of the present disclosure.

FIG. 2 illustrates a sectional view of another embodiment of a microlens array constructed according to aspects of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. Moreover, the formation of a first feature over or on a second feature in the description that follows may include embodiments in which the first and second features are formed in direct contact, and may also include embodiments in which additional features may be formed interposing the first and second features, such that the first and second features may not be in direct contact.

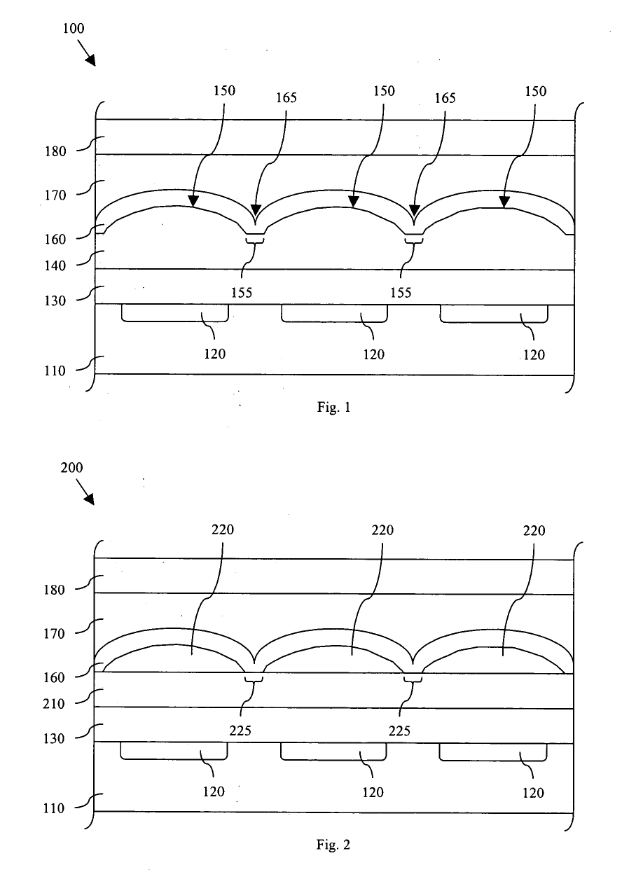

Referring to FIG. 1, illustrated is a sectional view of one embodiment of a microlens array 100 constructed according to aspects of the present disclosure. The microlens array includes, or may include, a substrate 110 having photo sensors 120 formed therein, a passivation layer 130, and a dielectric layer 140 having microlenses 150 formed therein, thereon, and/or therefrom. The microlens array 100 also includes a dielectric film 160, and possibly a color filter 170 and a protective layer 180.

The substrate 110 may comprise an elementary semiconductor (such as crystal silicon, polycrystalline silicon, amorphous silicon and germanium), a compound semiconductor (such as silicon carbide and gallium arsenide), an alloy semiconductor (such as silicon germanium, gallium arsenide phosphide, aluminum indium arsenide, aluminum gallium arsenide and gallium indium phosphide), combinations thereof, and/or other materials. The substrate 110 may also comprise a semiconductor material on an insulator, such as a silicon-on-insulator (SOI) substrate, a silicon on sapphire (SOS) substrate, or a thin film transistor (TFT) layer over glass and/or other materials. In one embodiment, the substrate 110 may also include a doped epitaxial layer, a multiple silicon structure, or a multilayer, compound semiconductor structure.

The photo sensors 120 may be photodiodes and/or other sensors diffused or otherwise formed in the substrate 110. Aspects of the present disclosure are applicable and/or readily adaptable to microlens arrays employing charged coupling device (CCD) and complimentary metal-oxide-semiconductor (CMOS) image sensor applications (e.g., active-pixel sensors), among others. As such, the photo sensors 120 may comprise conventional and/or future-developed image sensing devices. Moreover, the photo sensors 120 may comprise color image sensors and/or monochromatic image sensors.

The passivation layer 130 may comprise silicon nitride (e.g., Si₃N₄), silicon oxynitride (e.g., SiₓN_{y}O_{z}), silicon oxide, silicon dioxide, and/or other materials. The passivation layer 130 may be substantially optically transparent, and may be formed by chemical vapor deposition (CVD), plasma enhanced CVD (PECVD), physical vapor deposition (PVD), atomic layer deposition (ALD), evaporation, spin-on coating, and/or other processes. In one embodiment, the passivation layer 130 has a thickness ranging between about 1 μm and about 50 μm.

The dielectric layer 140 may comprise silicon nitride (e.g., Si₃N₄), silicon oxynitride (e.g., SiₓN_{y}O_{z}), silicon oxide, silicon dioxide, and/or other materials. The dielectric layer 140 may also be a low-k dielectric layer having a dielectric constant less than or equal to about 3.9. The dielectric layer 140 may be formed by CVD, PECVD, PVD, ALD, evaporation, spin-on coating, and/or other processes. In one embodiment, the dielectric layer 140 has a thickness ranging between about 0.2 μm and about 50 μm.

The microlenses 150 may be defined in and/or formed from the dielectric layer 140. However, in other embodiments, the microlenses may be distinct elements formed on, bonded to, and/or otherwise coupled directly or indirectly to the dielectric layer 140. In one embodiment, the microlenses 150 are formed from the dielectric layer 140 by employing a mask to pattern the dielectric layer 140 and subsequently heating the dielectric layer 140 such that the substantially convex profile shown in FIG. 1 is created. Such a mask may be formed by depositing a photoresist, polymer, and/or other material layer over the dielectric layer 140 and subsequently patterning the mask material. Each of the microlenses 150 may be substantially aligned with a corresponding photo sensor 120.

Such fabrication of the microlenses 150, and other fabrication methods and processes not necessarily described herein but within the scope of the present disclosure, may form gaps 155 between the microlenses 150. For example, substantially planar portions of the dielectric layer 140 may remain between the microlenses 150 after the microlenses 150 are formed. The gaps 155 may prevent portions of the incident light from being accurately directed toward the photo sensors 120. The dielectric film 160 at least partially fills the gaps 155 between the microlenses 150. For example, in the illustrated embodiment, the dielectric film 160 forms points 165 near the midpoints of the gaps 155. Consequently, a greater portion of the incident light may be accurately directed toward the photo sensors 120. Accordingly, the microlenses 150 and/or the microlens array 100 may exhibit a fill factor of at least about 50%.

The dielectric film 160 is conformally formed over the microlenses 150, such as by CVD, PECVD, PVD, ALD, evaporation, spin-on coating, and/or other processes. The dielectric film 160 may have a thickness ranging between about 1 μm and about 50 μm. The dielectric film 160 may comprise silicon nitride (e.g., Si₃N₄), silicon oxynitride (e.g., SiₓN_{y}O_{z}), silicon oxide, silicon dioxide, and/or other materials. The dielectric film 160 may also be a low-k dielectric film, possibly having a dielectric constant less than or equal to about 3.9.

In one embodiment, the dielectric film 160 and the microlenses 150 have substantially similar or equivalent compositions, although they are separate, distinct components. In another embodiment, the dielectric film 160 and the microlenses 150 have different compositions. For example, the composition of the dielectric film 160 may be selected such that the refractive indexes of the dielectric film 160 and the microlenses 150 are different. In one such application, the dielectric film 160 may have an index of refraction that is less than the index of refraction of the microlenses 150, such that the dielectric film 160 may be an anti-reflective layer.

The color filter 170 may include a color filter layer adjacent and/or interposing one or more color-transparent layers. In one embodiment, such color-transparent layers may comprise a polymeric material (e.g., negative photoresist based on an acrylic polymer) or resin, possibly having an index of refraction that is lower than that of the microlenses 150. The color filter layer may comprise negative photoresist based on an acrylic polymer including color pigments.

The protective layer 180 may comprise a transparent and/or optically transparent cement layer, such as a novolac epoxy resin, applied over the color filter 170. The protective layer 180 may also comprise a packaging substrate or layer, possibly comprising glass, which may be formed on the cement layer or otherwise coupled to the color filter 170.

Referring to FIG. 2, illustrated is a sectional view of another embodiment of the microlens array 100 shown in FIG. 1, herein designated by the reference numeral 200. The microlens array 200 includes, or may include, the substrate 110, the photo sensors 120, the passivation layer 130, the dielectric film 160, the color filter 170, and the protective layer 180, as described above with reference to FIG. 1. The microlens array 200 also includes a dielectric layer 210 which may be substantially similar in composition and manufacture to the dielectric layer 140 shown in FIG. 1. However, the dielectric layer 210 does not include the microlenses 150 shown in FIG. 1. In contrast, a substantial portion of the dielectric layer 210 in addition to the gaps described above may be substantially planar, possibly the result of chemical-mechanical-polishing and/or chemical-mechanical-planarizing (collectively referred to herein as CMP).

The microlens array 200 also includes microlenses 220 which may be substantially similar in composition and manufacture to the microlenses 150 shown in FIG. 1. However, the microlenses 220 may be formed by depositing a polymer, photoresist, and/or other microlens material over the dielectric layer 210 and subsequently patterning the microlens material. The patterned microlens material may then be heated to form the substantially convex profile shown in FIG. 2. Each of the microlenses 220 may also be substantially aligned with a corresponding photo sensor 120.

As with the embodiment discussed above, gaps 225 may form between the microlenses 220 during their fabrication. However, the gaps 225 may be reduced in size or substantially eliminated by the conformal deposition of the dielectric film 160. Consequently, the microlenses 220 and/or the microlens array 200 may exhibit a fill factor of at least about 50%.

Thus, the present disclosure provides a microlens device including, in one embodiment, a substrate having a photo sensor located therein and a microlens located over the substrate and including a substantially convex portion substantially aligned over the photo sensor. A dielectric film is located over and conforms to the microlens. A protective layer is located over the dielectric film.

The present disclosure also introduces a microlens array including a substrate having a plurality of photo sensors located therein and a microlens layer comprising a plurality of microlenses located over the substrate. Each of the plurality of microlenses includes a substantially convex portion substantially aligned over a corresponding one of the plurality of photo sensors. The plurality of microlenses are also separated by a plurality of gaps. The microlens array also includes a dielectric film located over and conforming to the microlens layer and substantially filling the plurality of gaps.

A method of manufacturing a microlens array is also provided in the present disclosure. In one embodiment, the method includes providing a substrate having a plurality of photo sensors located therein and forming a microlens layer comprising a plurality of microlenses over the substrate. Each of the plurality of microlenses includes a substantially convex portion substantially aligned over a corresponding one of the plurality of photo sensors. The plurality of microlenses are separated by a plurality of gaps. The method also includes forming a dielectric film over and conforming to the microlens layer and substantially filling the plurality of gaps.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A microlens device, comprising:
a substrate having a photo sensor located therein;
a microlens located over the substrate and including a substantially convex portion substantially aligned over the photo sensor;
a dielectric film located over and conforming to the microlens; and
a protective layer located over the dielectric film.

2. The microlens device of claim 1 further comprising a dielectric layer interposing the microlens and the substrate.

3. The microlens device of claim 1 wherein the dielectric film comprises a first composition and the microlens comprises a second composition that is substantially similar to the first composition.

4. The microlens device of claim 1 wherein the dielectric film has a first refractive index and the microlens has a second refractive index different than the first refractive index.

5. The microlens device of claim 1 wherein the dielectric film is an anti-reflective film.

6. The microlens device of claim 1 wherein the microlens comprises a polymer material.

7. The microlens device of claim 1 wherein the microlens comprises a dielectric material.

8. The microlens device of claim 1 further comprising a color filter layer located over the protective layer.

9. The microlens device of claim 1 wherein a fill factor corresponding to a ratio of light incident on the microlens device and the photo sensor is at least about 50%.

10. A microlens array, comprising:
a substrate having a plurality of photo sensors located therein;
a microlens layer comprising a plurality of microlenses located over the substrate, each of the plurality of microlenses including a substantially convex portion substantially aligned over a corresponding one of the plurality of photo sensors, wherein the plurality of microlenses are separated by a plurality of gaps; and
a dielectric film located over and conforming to the microlens layer and substantially filling the plurality of gaps.

11. The microlens array of claim 10 further comprising a protective layer located over the dielectric film.

12. The microlens array of claim 10 further comprising a dielectric layer interposing the microlens layer and the substrate.

13. The microlens array of claim 10 wherein the dielectric film comprises a first composition and the microlens layer comprises a second composition that is substantially similar to the first composition.

14. The microlens array of claim 10 wherein the dielectric film has a first refractive index and the microlens layer has a second refractive index different than the first refractive index.

15. The microlens array of claim 10 wherein the dielectric film is an anti-reflective film.

16. The microlens array of claim 10 wherein the microlens layer comprises a polymer material.

17. The microlens array of claim 10 wherein the microlens layer comprises a dielectric material.

18. The microlens array of claim 10 further comprising:
a protective layer located over the dielectric film; and
a color filter layer located over the protective layer.

19. The microlens array of claim 10 wherein a fill factor corresponding to a ratio of light incident on the microlens array and the plurality of photo sensors is at least about 50%.

20. A method of manufacturing a microlens array, comprising:
providing a substrate having a plurality of photo sensors located therein;
forming a microlens layer comprising a plurality of microlenses over the substrate, each of the plurality of microlenses including a substantially convex portion substantially aligned over a corresponding one of the plurality of photo sensors, wherein the plurality of microlenses are separated by a plurality of gaps; and
forming a dielectric film over and conforming to the microlens layer and substantially filling the plurality of gaps.

21. The method of claim 20 further comprising forming a protective layer over the dielectric film.

22. The method of claim 20 further comprising forming a dielectric layer interposing the microlens layer and the substrate.

23. The method of claim 22 wherein forming the microlens layer comprises:
depositing a microlens material layer over the dielectric layer;
patterning the microlens material layer; and
heating the patterned microlens material layer to form the plurality of microlenses.

24. The method of claim 23 wherein the microlens material layer comprises a polymer material.

25. The method of claim 20 wherein forming the microlens layer comprises:
depositing a microlens material layer over the substrate;
forming a mask over the microlens material layer; and
etching the microlens material layer employing the mask.

26. The method of claim 25 wherein the microlens material layer comprises a dielectric material.

27. The method of claim 20 further comprising:
forming a protective layer over the dielectric film; and
forming a color filter layer over the protective layer.
